(19) United States
(12) Patent Application Publication
(10) Pub. No.: US 2026/0018425 A1
(43) Pub. Date: Jan. 15, 2026

(54) METHOD FOR THE PRODUCTION OF A COOLING APPARATUS FOR A SEMICONDUCTOR ARRANGEMENT

(71) Applicant: Siemens Aktiengesellschaft, Munchen (DE)

(72) Inventors: Alexander Kiesel, Garmisch-Partenkirchen (DE); Florian Schwarz, Gerhardshofen (DE); Claus Brede, Erlangen (DE)

(73) Assignee: Siemens Aktiengesellschaft, Munchen (DE)

(21) Appl. No.: 19/265,830

(22) Filed: Jul. 10, 2025

(30) Foreign Application Priority Data
Jul. 11, 2024 (EP) 24188071.5

(51) Int. Cl. H01L 21/48; H01L 23/367; H01L 23/427

(52) U.S. Cl. CPC H01L 21/4878; H01L 23/3672; H01L 23/427

(57) ABSTRACT

A cooling apparatus for a semiconductor arrangement is made by producing a base body with a flat surface, opposing first and second lateral surfaces, and channels extending continuously from the first to the second lateral surface and parallel to the flat surface, with adjacent ones of the channels being each connected via a web. Bilaterally introduced in the base body are contacting grooves and connecting grooves in parallel relation to the flat surface by partially removing the web between the adjacent channels such that the connecting grooves are arranged between the adjacent channels, the channels are arranged between the flat surface and the contacting grooves, and the connecting grooves protrude deeper into the base body than the respective contacting grooves. The channels are closed to form a closed channel structure which is filled with a heat transfer fluid so that the base body is directly contacting the heat transfer fluid.

### CROSS-REFERENCES TO RELATED APPLICATIONS

This application claims the priority of European Patent Application, Serial No. EP 24188071.5, filed Jul. 11, 2024, pursuant to 35 U.S.C. 119 (a)-(d), the disclosure of which is incorporated herein by reference in its entirety as if fully set forth herein.

### BACKGROUND OF THE INVENTION

The invention relates to a method for the production of a cooling apparatus for a semiconductor arrangement, to a cooling apparatus for a semiconductor arrangement, to a semiconductor arrangement with such a cooling apparatus, and to a power converter with such a semiconductor arrangement.

The following discussion of related art is provided to assist the reader in understanding the advantages of the invention, and is not to be construed as an admission that this related art is prior art to this invention.

In general, a cooling apparatus is used in a power converter, such as, e.g. a rectifier, an inverter, a converter or a DC-DC converter.

With progressive miniaturization in construction and connection technology, for example by planar construction and connection technology, the power density in power converters is increasing. In order to avoid electronic failures as a result of thermal overloads, increasingly effective but also more affordable concepts are therefore required for cooling semiconductor elements.

It would therefore be desirable and advantageous to address this problem and to obviate other prior art shortcomings.

### SUMMARY OF THE INVENTION

According to one aspect of the invention, a method for producing a cooling apparatus for a semiconductor arrangement includes producing a base body with a flat surface, a first lateral surface, a second lateral surface in opposition to the first lateral surface, and channels to extend continuously from the first lateral surface to the second lateral surface and parallel to the flat surface, with adjacent ones of the channels being each connected via a web, bilaterally introducing contacting grooves and connecting grooves in parallel relation to the flat surface by partially removing the web between the adjacent ones of the channels such that the connecting grooves are arranged between the adjacent ones of the channels, the channels are arranged between the flat surface and the contacting grooves, and the connecting grooves protrude deeper into the base body than the respective contacting grooves, closing the channels by pressing to form a closed channel structure, and filling the channel structure with a heat transfer fluid so that the base body is in direct contact with the heat transfer fluid.

According to another aspect of the invention, a cooling apparatus for a semiconductor arrangement includes a base body, in particular a metallic base body, including a flat surface, a first lateral surface, a second lateral surface in opposition to the first lateral surface, and channels to extend continuously from the first lateral surface to the second lateral surface and parallel to the flat surface, with adjacent ones of the channels being each connected via a web, with the base body including contacting grooves and connecting grooves in parallel relation to the flat surface by partially removing the web between the adjacent ones of the channels such that the connecting grooves are arranged between the adjacent ones of the channels, the channels are arranged between the flat surface and the contacting grooves, and the connecting grooves protrude deeper into the base body than the respective contacting grooves, wherein the channels have channel ends which have been pressed to form a closed channel structure, and a heat transfer fluid arranged in the closed channel structure so that the base body is in direct contact with the heat transfer fluid.

According to yet another aspect of the invention, a semiconductor arrangement includes the cooling apparatus as set forth above, a substrate connected to the flat surface of the base body, in particular bonded to the flat surface of the base body with material-locking connection, and power semiconductor elements contacted on the substrate in such a way that any loss occurring in the power semiconductor elements during operation of the semiconductor arrangement is transferred via the substrate to the channel structure filled with the heat transfer fluid.

According to still another aspect of the invention, a power converter includes such a semiconductor arrangement.

Advantages and preferred embodiments described hereinafter in relation to the method can be applied correspondingly to the cooling apparatus, the semiconductor arrangement and the power converter.

An objective of the invention is to simplify the production of a cooling apparatus with a closed channel structure which can be used, for example, as a heat pipe, in particular a pulsating heat pipe, and/or vapor chamber by sealing continuous channels running parallel to a flat surface of a base body as simply and cost-effectively as possible, in particular hermetically, in such a way that the closed channel structure is formed. In addition to the flat surface, the base body has a first lateral surface and a second lateral surface arranged opposite the first lateral surface. Advantageously, the first lateral surface and the second lateral surface can be essentially flat and arranged parallel to each other. For example, the base body can be cuboid in design. Webs of the base body are arranged between adjacent channels. In particular, adjacent channels are each separated by a web of the base body. Adjacent channels are connected to one another by introducing connecting grooves, with the connecting grooves being introduced through partial removal of webs in the area of the lateral surface. The connecting grooves protrude deeper into the base body than the respective contacting grooves. For example, the partial removal of the webs and the introduction of the contacting grooves running parallel to the surface of the base body can be carried out in one production step.

In a further step, the channels are closed through pressing to form the closed channel structure, with the contacting grooves being used to contact a pressing apparatus. For example, a base plate can be inserted into the contacting groove, with a punch being placed above the base plate on the flat surface and pressed, in particular perpendicularly, in the direction of the base plate. As the connecting grooves protrude deeper into the base body than the respective contacting grooves, the respective channels of the channel structure are fluidically connected to one another by the connecting grooves, which form connection channels between the channels. Such a non-positive connection through pressing is reliable as well as simple and cost-effective to produce. As a result of the lateral sealing of the channels, in particular in comparison to a two-part construction, smaller tools can be used, which also reduces costs. In a further step, the channel structure is filled with a heat transfer fluid so that the base body is in direct contact with the heat transfer fluid. Filling can take place, for example, via a filling opening which is hermetically sealed after filling. A cooling apparatus produced by such a method can be operated, for example, as a heat pipe, in particular a pulsating heat pipe, and/or vapor chamber.

According to another advantageous feature of the invention, the connecting grooves can be arranged alternately in an area of the lateral surfaces to form a meander channel structure. Such a meander channel structure achieves homogeneous heat dissipation over a large area.

According to another advantageous feature of the invention, the base body can be produced from a metallic material through extrusion. In particular, the base body can be produced as a continuous profile from aluminum or an aluminum alloy by extrusion. For example, an aluminum alloy with a silicon content of up to 1.0%, in particular up to 0.6%, can be used for extrusion. Thus, during extrusion, a low silicon content can be used, in particular in comparison with a cast base body, so that improved thermal conductivity can be obtained through extrusion with such an alloy. In addition, extrusion, in particular of continuous profiles, is simple and cost-effective. In particular, when using aluminum or an aluminum alloy, which are rather soft in terms of their material properties, for example in comparison with other metallic materials with similar thermal conductivity, cost-effective encapsulation can be produced by extrusion.

According to another advantageous feature of the invention, cooling fins running parallel to the channels can be produced during extrusion. As a result, the cooling fins can also be produced as a continuous profile by extrusion, which simplifies the manufacturing process as well as saving costs.

According to another advantageous feature of the invention, the channels can be pressed by using a gripper, with a first gripper jaw of the gripper contacting on the flat surface of the base body, a second gripper jaw of the gripper contacting on a contacting surface of each of the contacting grooves, and with the first and second gripper jaws of the gripper being pressed together to seal the channel. Pressing by applying such a gripper is quick, simple and cost-effective. In addition, the pressing together of gripper jaws obtains a more reliable press connection, in particular in comparison with a pressing apparatus with a punch and a base plate. Advantageously, the contacting surface extends in parallel relation to the flat surface of the base body.

According to another advantageous feature of the invention, the contacting grooves and connecting grooves can be introduced by a machining process, e.g. milling. Milling is simple and cost-effective.

According to another advantageous feature of the invention, a sealant, advantageously a metallic sealant, can be inserted into at least one of the channels and also pressed before sealing. Such a sealant can be, inter alia, a metallic sealant which, for example, differs from the metallic material of the base body in terms of its strength. Inter alia, the metallic sealant can be softer than the metallic material of the base body. For example, the metallic sealant may contain copper, zinc and/or tin. In addition or alternatively, the sealant may contain an organic material. The organic material can be, inter alia, sealing tape or rubber. An additional improvement in the impermeability of the press connection is achieved in a simple and cost-effective manner by such a sealant.

According to another advantageous feature of the invention, the closing of the channels can include a material-locking connection of the channel ends. For example, the material-locking connection takes place after pressing. Such a material-locking connection can be produced, inter alia, by welding, hard soldering or bonding, the impermeability of the channel structure being improved and thus the service life of the cooling apparatus being increased.

According to another advantageous feature of the invention, a removal of webs arranged between adjacent channels in the area of a lateral surface can take place at different depths, an inner pressing and an outer pressing being carried out, in particular to produce a deflection channel on the lateral surface. A closed-loop pulsating heat pipe can be produced in a simple and cost-effective manner via a deflection channel produced by internal and external pressing on one side.

According to another advantageous feature of the invention, first inner ones of the webs can be removed at a first depth which is deeper than a second depth of the contacting groove, and second ones of the webs can be removed at a third depth which is less deep than the first depth of the contacting groove, wherein a removal of the first inner ones of the webs and a removal of the second ones of the webs takes place alternately between the second depth and the third depth. As a result, a meander channel structure, which can achieve homogeneous heat dissipation over a large area, can be produced in a simple and cost-effective manner.

According to another advantageous feature of the invention, inner ones of the channels can be closed by inner pressing such as to form an inner pressing zone which seals the inner channels by forming a meander structure, and outer ones of the channels can be closed by outer pressing such as to form a deflection channel to thereby form a closed-loop pulsating heat pipe by the deflection channel. As a result, a closed-loop pulsating heat pipe with a meander channel structure can be produced in a simple and cost-effective manner.

According to another advantageous feature of the invention, a substrate can be connected to the flat surface, advantageously bonded to the flat surface with a material-locking connection, and power semiconductor elements can be contacted on the substrate in such a way that the power semiconductor elements are in a thermally conductive connection with the channel structure filled with the heat transfer fluid. Inter alia, the substrate can be designed as a ceramic substrate, in particular as a DCB (Direct-Copper-Bonded) substrate, so that an electrically insulating and thermally conductive connection of the power semiconductor elements to the base body is produced. For example, a metallization of the substrate can be connected to the surface of the cooling apparatus by soldering or sintering, with the power semiconductor elements being connected by soldering or sintering to a metallization arranged on an opposite side of the substrate.

According to another advantageous feature of the invention, a pressing zone can be formed on both sides at the channel ends of the channels to delimit the connecting groove, with the pressing zone being spaced apart from the webs in such a way that a channel cross-section in the area of the connecting groove essentially corresponds to a channel cross-section of the channels. Such an embodiment of the connection channels between the channels, which are formed by the connecting grooves, enables efficient heat dissipation.

### BRIEF DESCRIPTION OF THE DRAWING

Other features and advantages of the present invention will be more readily apparent upon reading the following description of currently preferred exemplified embodiments of the invention with reference to the accompanying drawing, in which:

FIG. 1 shows a schematic sectional view of a base body for a cooling apparatus;

FIG. 2 shows a schematic three-dimensional view of the base body in the area of the first lateral surface;

FIG. 3 shows a schematic three-dimensional sectional view of the base body in the area of the first lateral surface;

FIG. 4 shows a schematic three-dimensional sectional view of the base body in the area of a second lateral surface;

FIG. 5 shows a schematic view of a method for the production of a first embodiment of a cooling apparatus with a base body;

FIG. 6 shows a schematic three-dimensional view of the pressing of channels by a gripper;

FIG. 7 shows a schematic sectional view of a second embodiment of a cooling apparatus in the area of the first lateral surface;

FIG. 8 shows a schematic view of a method for the production of the second embodiment of the cooling apparatus in a cross-section in the area of the first lateral surface;

FIG. 9 shows a schematic view of the method for the production of the second embodiment of the cooling apparatus in a longitudinal section in the area of the first lateral surface;

FIG. 10 shows a schematic sectional view of a semiconductor arrangement with a cooling apparatus; and

FIG. 11 shows a schematic view of a power converter.

### DETAILED DESCRIPTION OF PREFERRED EMBODIMENTS

Throughout all the figures, same or corresponding elements may generally be indicated by same reference numerals. These depicted embodiments are to be understood as illustrative of the invention and not as limiting in any way. The described components of the embodiments each represent individual features of the invention to be considered independently of one another, which also develop the invention in each case independently of one another and are thus also to be regarded as part of the invention independently or in a combination other than that shown. Furthermore, the embodiments described can also be supplemented by other features of the invention already described. It should also be understood that the figures are not necessarily to scale and that the embodiments may be illustrated by graphic symbols, phantom lines, diagrammatic representations and fragmentary views. In certain instances, details which are not necessary for an understanding of the present invention or which render other details difficult to perceive may have been omitted.

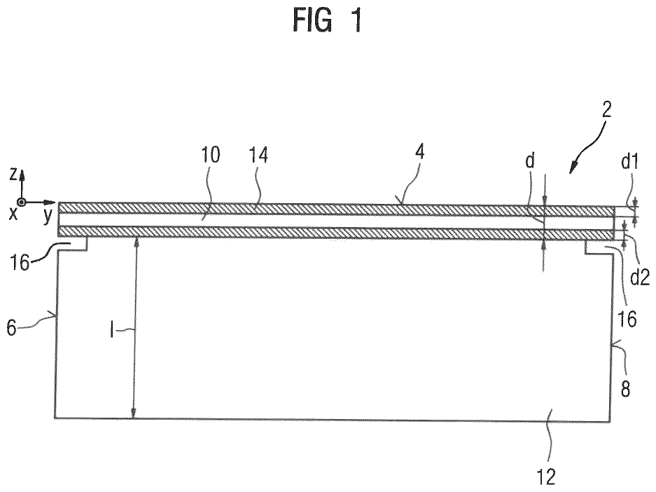

Turning now to the drawing, and in particular to FIG. 1, there is shown a schematic sectional view of a base body, generally designed by reference numeral 2, for a cooling apparatus which is produced from a metallic material, for example from aluminum or an aluminum alloy, through extrusion, in particular as a continuous profile. For example, an aluminum alloy with a silicon content of up to 1.0%, in particular up to 0.6%, is used for extrusion. In particular, in comparison with a cast base body 2, improved thermal conductivity is obtained using an extruded base body 2 as a low silicon content can be used during extrusion. An extruded base body from such an aluminum alloy enables an improved heat splay. Alternatively, the base body 2 with the channels 10 running parallel to one another can be produced from a thermally conductive plastic, in particular as a continuous profile, through plastic extrusion.

The essentially cuboid base body 2 has a flat surface 4, a first lateral surface 6 and a second lateral surface 8 arranged opposite the first lateral surface 6. The flat surface 4 defines an xy-plane, a z-axis running perpendicular to the flat surface. Using the extrusion method, channels 10 and cooling fins 12 extending continuously from the first lateral surface 6 to the second lateral surface 8 are formed in the base body 2, with the channels 10 being introduced parallel to the surface 4. A thickness d of a base plate 14 of the base body 2 is defined by a length l of the inserted cooling fins 12. The channels 10 and the cooling fins 12 are arranged in parallel and, for example, in the y-direction. The cooling fins 12, for example running parallel to one another, are configured to be surrounded by a coolant, in particular a gaseous coolant. In addition, the channels 10 are essentially introduced centrally into the base plate 14 of the base body 2 so that a first thickness d1 of the metallic material above the channels 10 and a second thickness d2 of the metallic material below the channels 10 are constant and essentially the same. Furthermore, contacting grooves 16 running parallel to the surface 4 are introduced into the two lateral surfaces 6, 8. For example, the contacting grooves 16 are introduced into the base body by a machining process, for example milling. For example, the contacting grooves 16 are milled out in the area of the cooling fins 12.

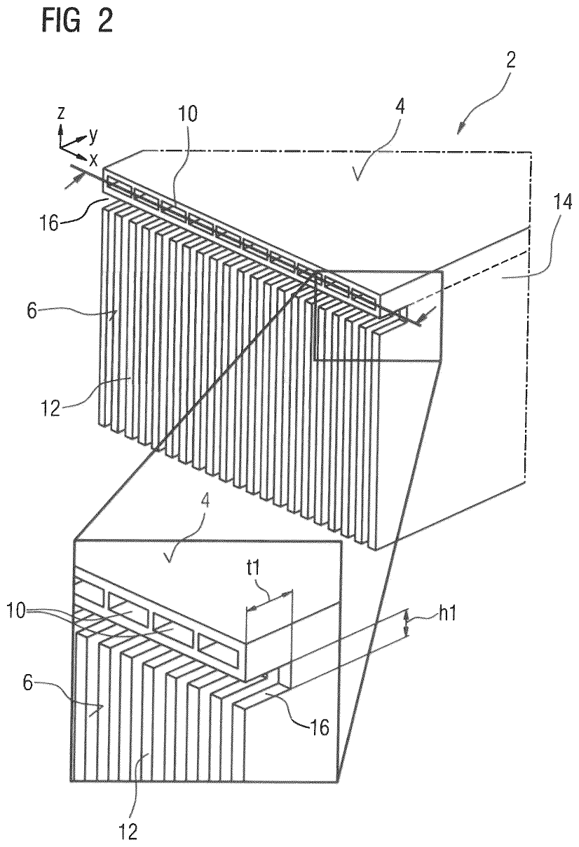

FIG. 2 shows a schematic three-dimensional view of the base body 2 in the area of the first lateral surface 6. A height h1 and a first depth t1 of the contacting groove 16 are dimensioned in such a way that, for example, gripper jaws of a gripper can be used to press the channels. The channels 10 running parallel to one another and to the surface 4 have an essentially identical rectangular, in particular square, cross-sectional area. For example, the channel cross-section is 2×2 mm². In addition, the channels 10 are arranged equidistant to one another. The further embodiment of the base body 2 in FIG. 2 corresponds to that in FIG. 1.

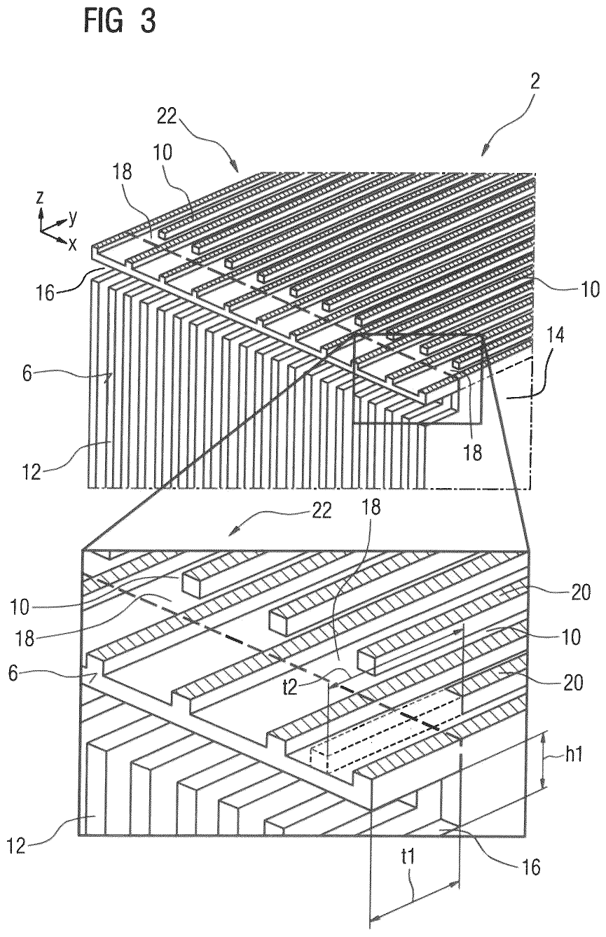

FIG. 3 shows a schematic three-dimensional sectional view of the base body in the area of the first lateral surface, with connecting grooves 18 between adjacent channels 10 being introduced by a partial removal of webs 20 arranged between the adjacent channels 10. Removal takes place, for example, using machining processes such as milling. A second depth t2 of the connecting grooves 18 is greater than the first depth t1 of the contacting grooves 16 so that the connecting grooves 18 protrude deeper into the base body 2 than the contacting grooves 16. For example, the connecting grooves 18 are arranged alternately in the area of the two lateral surfaces 6, 8 to form a meander channel structure 22. The further embodiment of the base body 2 in FIG. 3 corresponds to that in FIG. 2.

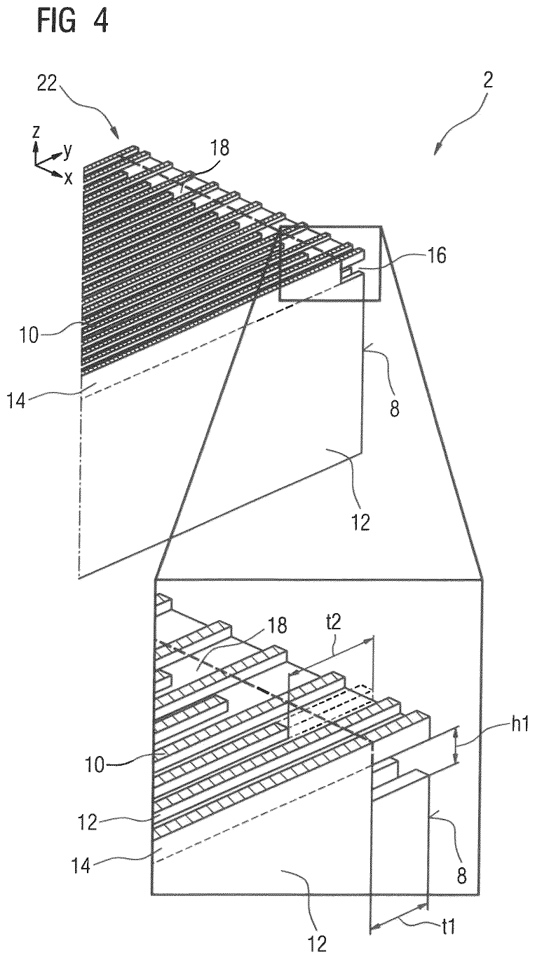

FIG. 4 shows a schematic three-dimensional sectional view of the base body 2 in the area of a second lateral surface 8. The base body 2 from FIGS. 3 and 4 is symmetrical with respect to a yz-plane.

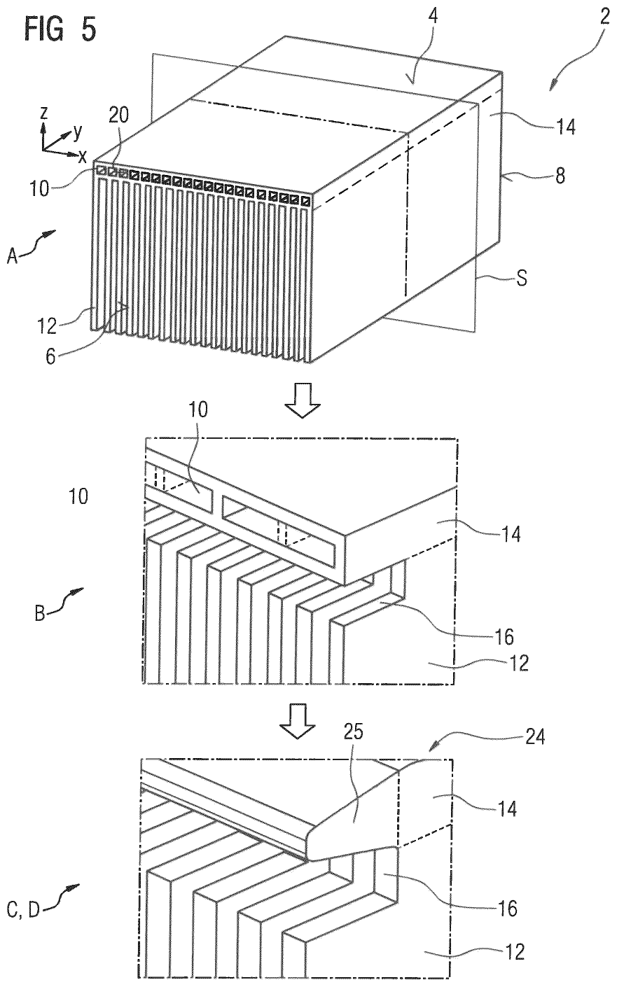

FIG. 5 shows a method for the production of a first embodiment of a cooling apparatus 24 with a base body 2 which is described in the previous figures. The method comprises the production A of the metallic base body 2 using an extrusion method. The base body 2 is cuboid in design, having flat lateral surfaces 6, 8 arranged parallel to one another and a flat surface 4 arranged perpendicularly to the lateral surfaces 6, 8. Channels 10 and cooling fins 12 extending continuously from the first lateral surface 6 to the second lateral surface 8 are introduced into the base body 2 through extrusion, with adjacent channels 10 each being connected via a web 20. The base body 2 is symmetrical with respect to a symmetry plane S extending in the yz-plane.

In a further step, bilateral insertion B of contacting grooves 16 and connecting grooves 18 running parallel to the surface 4 takes place, with the connecting grooves 18 between adjacent channels 10 being formed by partial removal of the web 20 arranged between the adjacent channels 10. The contacting grooves 16 are introduced in such a way that the channels 10 are arranged between the surface 4 and the contacting grooves 16 and the connecting grooves 18 protrude deeper into the base body 2 than the respective contacting grooves 16. Removal can take place, inter alia, by a machining process, for example through milling. For example, the connecting grooves 18 alternate in the area of the lateral surfaces 6, 8 to form a meander channel structure 22.

In a further step, closing C of the channels 10 by pressing to form a closed channel structure 22 and filling D of the closed channel structure 22 with a heat transfer fluid takes place so that the base body 2 in the area of the channels 10 is in direct contact with the heat transfer fluid. As a result of the pressing, a pressing zone 25 which delimits the connecting grooves 18 is formed. The pressing zone 25 is spaced apart from the webs 20 in such a way that a channel cross-section in the area of the connecting groove 18 essentially corresponds to a channel cross-section of the channels 10.

In addition, the closing C of the channels 10 can include a material-locking connection of the channel ends. For example, a material-locking connection takes place after pressing. The material-locking connection can take place, inter alia, by welding, hard soldering or bonding and can improve the impermeability of the channel structure 22.

Optionally, prior to closing C, a sealant can be inserted into at least one of the channels 10 in the area of the press connection to be produced, with the sealant also being pressed, in order to obtain improved impermeability of the press connection. Such a sealant can be, inter alia, a metallic sealant which, for example, differs from the metallic material of the base body 2. The metallic sealant can be, inter alia, softer than the metallic material of the base body 2. For example, the metallic sealant can contain copper, zinc and/or tin. In addition or alternatively, the sealant can contain an organic material. The organic material can be, inter alia, sealing tape or rubber.

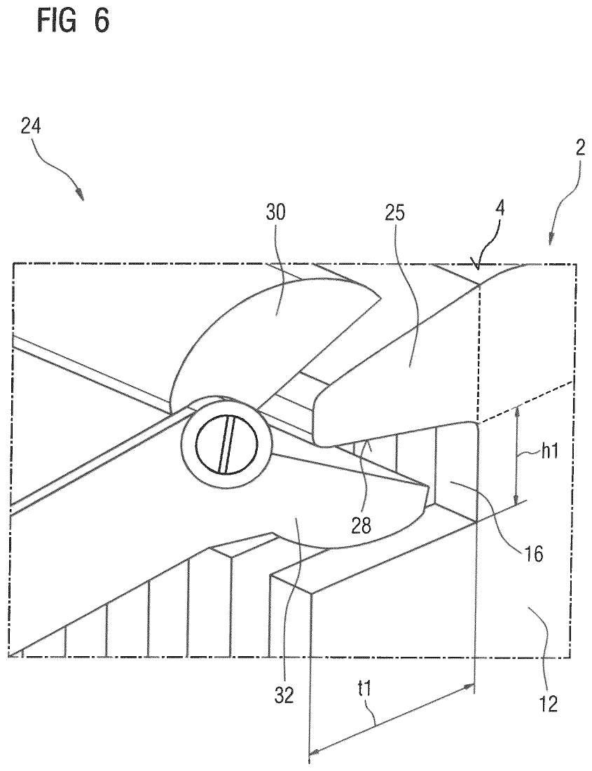

FIG. 6 shows a schematic three-dimensional view of the pressing of channels 10 by a gripper 26. The contacting groove 16 has a contacting surface 28 running parallel to the surface 4 of the base body 2, with a first gripper jaw 30 being contacted on the surface 4 of the base body 2 and a second gripper jaw 32 being contacted on the contacting surface 28 of the contacting groove 16 and the gripper jaws 30, 32 being pressed together to close the channels 10. Further or previous method steps for the production of the cooling apparatus 24 in FIG. 6 correspond to those in FIG. 5.

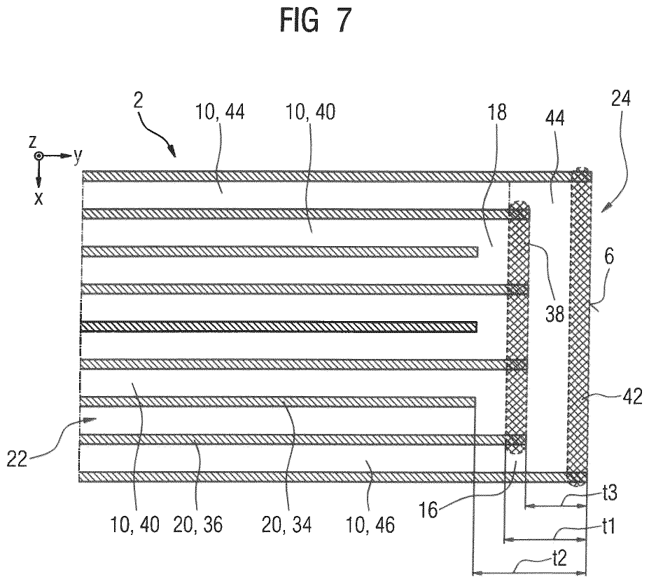

FIG. 7 shows a schematic sectional view of a second embodiment of a cooling apparatus 24 in the area of the first lateral surface 6, with the webs 20 arranged between adjacent channels 10 having been removed at different depths t2, t3. First inner webs 34 are removed at a second depth t2, which is deeper than a first depth t1 of the contacting groove 16, while second inner webs 36 are removed at a third depth t3 which is less deep than the first depth of the contacting groove 16. An inner pressing zone 38 closes inner channels 40 of the channel structure 22. The first inner webs 34 and the second inner webs 36 are arranged alternately to form a meander structure. An outer pressing zone 42 is designed for the production of a deflection channel 44 which connects the outer channels 46 of the channel structure 22. A closed-loop pulsating heat pipe (CLPHP) is formed by the deflection channel 44. The further embodiment of the cooling apparatus 24 in FIG. 7 corresponds to that in FIG. 5.

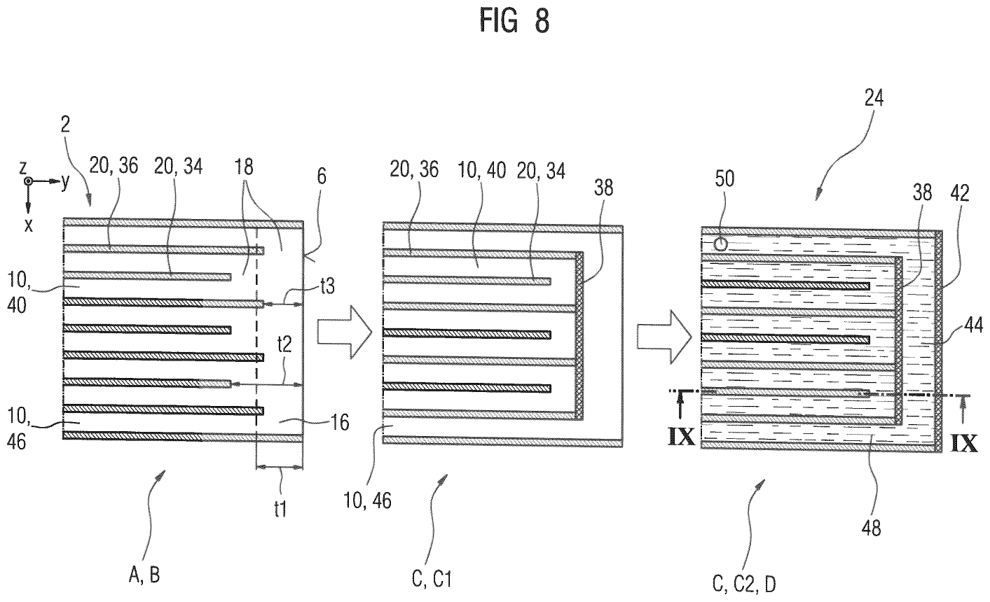

FIG. 8 shows a schematic view of a method for the production of the second embodiment of the cooling apparatus 24 in a cross-section in the area of the first lateral surface 6. After the production A of the metallic base body 2 by an extrusion method, the introduction B of contacting grooves 16 and connecting grooves 18 running parallel to the surface 4 takes place. The connecting grooves 18 are produced through partial removal of the webs 20 arranged between adjacent channels 10 at different depths t2, t3. Partial removal at different depths t2, t3 takes place alternately so that first inner webs 34 and second inner webs 36 are formed alternately. The production of the connecting grooves 18 in the area of the second lateral surface 8 takes place according to the method described in FIG. 5.

In a further step, a closing C of the inner channels 40 takes place by inner pressing C1, an inner pressing zone 38 being formed by way of inner pressing C1, which closes the inner channels 40 of the channel structure 22 in the area of the first lateral surface 6 so that a meander structure is formed.

In a further step, the closing C of the outer channels 46 takes place by outer pressing C2, with an outer pressing zone 42 being formed by way of outer pressing C2, which closes the outer channels 46 in the area of the first lateral surface 6. A deflection channel 44 is formed by the outer pressing zone 42, which connects the outer channels 46 of the channel structure 22. The closing C of the channels 10 in the area of the second lateral surface 8 takes place according to the method described in FIG. 5. Thereupon, filling D of the channel structure 22 takes place with a heat transfer fluid 48. Filling D is exemplified by a standard process via a filling opening 50 which is hermetically sealed after filling D. The further embodiment of the method in FIG. 8 corresponds to that in FIG. 5.

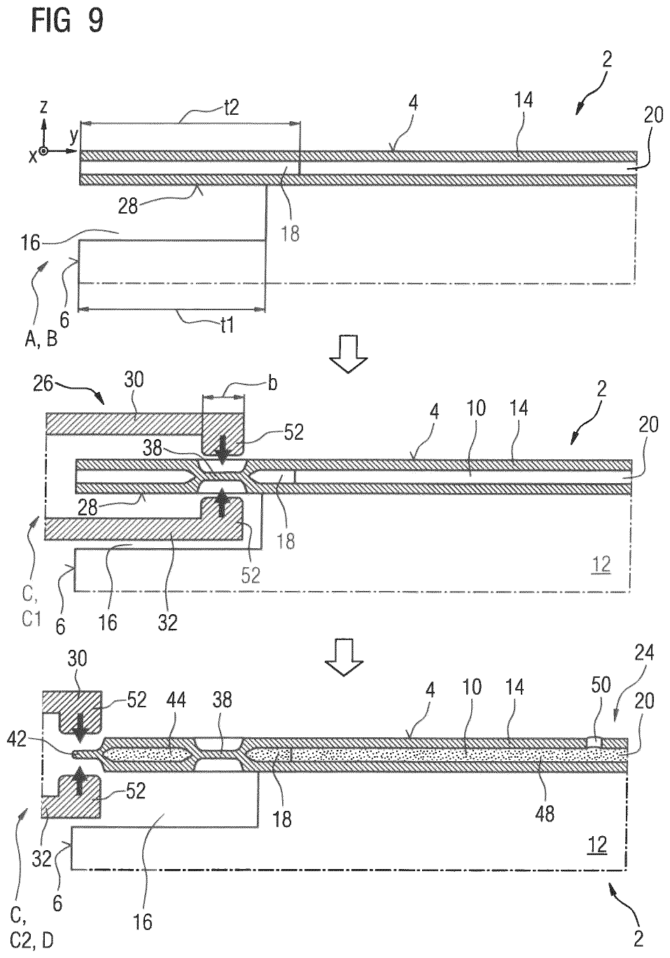

FIG. 9 shows a schematic view of the method for the production of the second embodiment of the cooling apparatus 24 in a longitudinal section in the area of the first lateral surface. The inner pressing C1 takes place by a gripper 26, with a first gripper jaw 30 being contacted on the surface 4 of the base body 2 and a second gripper jaw 32 being contacted on the contacting surface 28 of the contacting groove 16. The gripper jaws 30, 32 each have a punch 52 with a width b to form the inner pressing zone 38. The punches 52 of the gripper jaws 30, 32 are pressed together to close the channels 10. The inner pressing zone 38 is arranged in such a manner that a channel cross-section in the area of the connecting groove 18 essentially corresponds to a channel cross-section of the channels 10. The outer pressing C2 to form the outer pressing zone 42 is carried out using the example of the same gripper 26. The deflection channel 44 is formed by the outer pressing zone 42 and the inner pressing zone 38, with the pressing zones 38, 42 being spaced apart in such a manner that a channel cross-section of the deflection channel 44 essentially corresponds to a channel cross-section of the channels 10. Alternatively, the inner and outer pressing C1, C2 can take place at the same time by a gripper 26 which has two punches 52. The further embodiment of the method in FIG. 9 corresponds to that in FIG. 8.

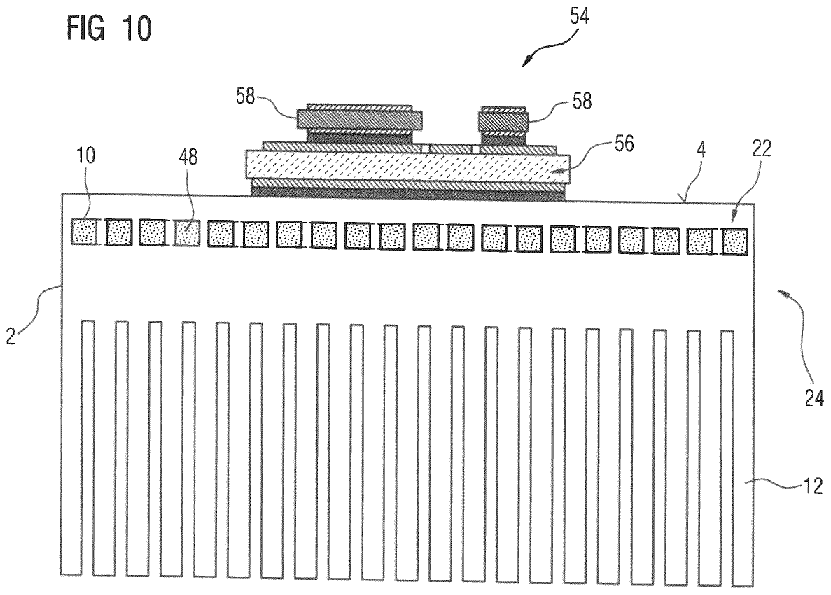

FIG. 10 shows a schematic sectional view of a semiconductor arrangement 54 with a cooling apparatus 24, with a ceramic substrate 56 being connected to the flat surface 4 of the cooling apparatus 24 via a material-locking connection. The cooling apparatus 24 can be designed, for example, as shown in FIG. 5 or FIG. 7. For example, the substrate 56 is connected to the surface 4 of the cooling apparatus 24 by soldering. Power semiconductor elements 58 are contacted on the substrate 56 in such a manner that they are in a thermally conductive connection with the channel structure 22 filled with the heat transfer fluid 48, so that a pulsating heat pipe is formed. For example, the power semiconductor elements 58 are connected to the substrate 56, which may be designed, inter alia, as a DCB substrate, by soldering.

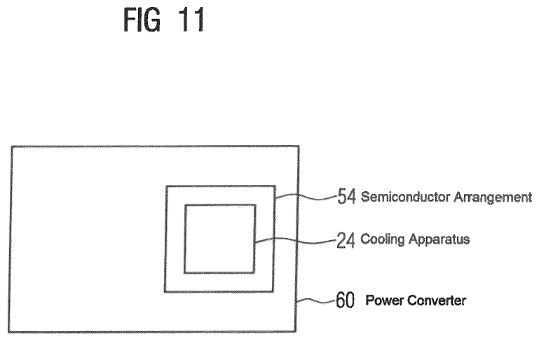

FIG. 11 shows a schematic view of a power converter 60 which comprises a semiconductor arrangement 54 as an example. The semiconductor arrangement 54 comprises a cooling apparatus 24.

In summary, the invention relates to a method for the production of a cooling apparatus 24 for a semiconductor arrangement 54. In order to enable simple and more cost-effective production, the following steps are proposed: production A of a base body 2, in particular a metallic base body 2, with a flat surface 4, a first lateral surface 6 and a second lateral surface 8 arranged opposite the first lateral surface 6, channels 10 extending continuously from the first lateral surface 6 to the second lateral surface 8 and parallel to the surface 4 being inserted into the base body 2, with adjacent channels 10 each being connected via a web 20, the bilateral introduction B of contacting grooves 16 and connecting grooves 18 extending parallel to the surface 4, with the connecting grooves 16 being arranged between adjacent channels 10 by a partial removal of the web 20 arranged between the adjacent channels 10, wherein the channels 10 are arranged between the surface 4 and the contacting grooves 16 and the connecting grooves 18 protrude deeper into the base body 2 than the respective contacting grooves 16, closing C of the channels 10 by pressing to form a closed channel structure 22, filling D of the channel structure 22 with a heat transfer fluid 48 so that the base body 2 is in direct contact with the heat transfer fluid 48.

While the invention has been illustrated and described in connection with currently preferred embodiments shown and described in detail, it is not intended to be limited to the details shown since various modifications and structural changes may be made without departing in any way from the spirit and scope of the present invention. The embodiments were chosen and described in order to explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and includes equivalents of the elements recited therein:

What is claimed is:

1. A method for producing a cooling apparatus for a semiconductor arrangement, the method comprising:
producing a base body with a flat surface, a first lateral surface, a second lateral surface in opposition to the first lateral surface, and channels to extend continuously from the first lateral surface to the second lateral surface and parallel to the flat surface, with adjacent ones of the channels being each connected via a web;
bilaterally introducing contacting grooves and connecting grooves in parallel relation to the flat surface by partially removing the web between the adjacent ones of the channels such that the connecting grooves are arranged between the adjacent ones of the channels, the channels are arranged between the flat surface and the contacting grooves, and the connecting grooves protrude deeper into the base body than the respective contacting grooves;
closing the channels by pressing to form a closed channel structure; and
filling the channel structure with a heat transfer fluid so that the base body is in direct contact with the heat transfer fluid.

2. The method of claim 1, wherein the base body is made of metal.

3. The method of claim 1, wherein the closed channel structure and the heat transfer fluid form a pulsating heat pipe.

4. The method of claim 1, further comprising arranging the connecting grooves alternately in an area of the first and second lateral surfaces so that the channel structure has a meandering configuration.

5. The method of claim 2, wherein the base body is produced through extrusion.

6. The method of claim 5, further comprising producing cooling fins in parallel relation to the channels during extrusion.

7. The method of claim 1, further comprising:
contacting a first gripper jaw of a gripper on the flat surface of the base body;
contacting a second gripper jaw of the gripper on a contacting surface of each of the contacting grooves; and
pressing the first and second gripper jaws of the gripper together to close the channel.

8. The method of claim 7, wherein the contacting surface extends in parallel relation to the flat surface of the base body.

9. The method of claim 1, wherein the contacting grooves and the connecting grooves are formed by machining.

10. The method of claim 1, further comprising:
inserting, prior to closing the channels, a sealant into at least one of the channels; and
pressing the sealant as the channels are closed by pressing.

11. The method of claim 10, wherein the sealant is a metallic sealant.

12. The method of claim 1, wherein the closing of the channels includes a material-locking connection of channel ends.

13. The method of claim 1, wherein a removal of the webs between adjacent ones of the channels takes place at different depths in an area of one of the first and second lateral surfaces, and wherein the channels are pressed by an inner pressing and an outer pressing to produce in particular a deflection channel on the one of first and second lateral surfaces.

14. The method of claim 13, further comprising:
removing first inner ones of the webs at a first depth which is deeper than a second depth of the contacting groove;
removing second ones of the webs at a third depth which is less deep than the first depth of the contacting groove,
wherein a removal of the first inner ones of the webs and a removal of the second ones of the webs takes place alternately between the second depth and the third depth.

15. The method as claimed in claim 1, further comprising:
closing inner ones of the channels by inner pressing such as to form an inner pressing zone which closes the inner channels by forming a meander structure; and
closing outer ones of the channels by outer pressing such as to form a deflection channel to thereby form a closed-loop pulsating heat pipe by the deflection channel.

16. The method of claim 1, further comprising:
connecting a substrate to the flat surface, in particular bonding the substrate to the flat surface with a material-locking connection; and
contacting power semiconductor elements in such a way that the power semiconductor elements are in a thermally conductive connection with the channel structure filled with the heat transfer fluid.

17. A cooling apparatus for a semiconductor arrangement, the cooling apparatus comprising:
a base body, in particular a metallic base body, including a flat surface, a first lateral surface, a second lateral surface in opposition to the first lateral surface, and channels to extend continuously from the first lateral surface to the second lateral surface and parallel to the flat surface, with adjacent ones of the channels being each connected via a web, said base body including contacting grooves and connecting grooves in parallel relation to the flat surface by partially removing the web between the adjacent ones of the channels such that the connecting grooves are arranged between the adjacent ones of the channels, the channels are arranged between the flat surface and the contacting grooves, and the connecting grooves protrude deeper into the base body than the respective contacting grooves, wherein the channels have channel ends which have been pressed to form a closed channel structure; and
a heat transfer fluid arranged in the closed channel structure so that the base body is in direct contact with the heat transfer fluid.

18. The cooling apparatus of claim 17, wherein the base body comprises a pressing zone on both sides at the channel ends of the channels to delimit the connecting groove, said pressing zone being spaced apart from the webs in such a way that a channel cross-section in an area of the connecting groove essentially corresponds to a channel cross-section of the channels.

19. A semiconductor arrangement, comprising:
the cooling apparatus of claim 17;
a substrate connected to the flat surface of the base body, in particular bonded to the flat surface of the base body with material-locking connection; and
power semiconductor elements contacted on the substrate in such a way that any loss occurring in the power semiconductor elements during operation of the semiconductor arrangement is transferred via the substrate to the channel structure filled with the heat transfer fluid.

20. A power converter, comprising a semiconductor arrangement, said semiconductor arrangement comprising the cooling apparatus of claim 17, a substrate connected to the flat surface of the base body, in particular bonded to the flat surface of the base body with material-locking connection, and power semiconductor elements contacted on the substrate in such a way that any loss occurring in the power semiconductor elements during operation of the semiconductor arrangement is transferred via the substrate to the channel structure filled with the heat transfer fluid.
